(19) United States
(12) Patent Application Publication
(10) Pub. No.: US 2018/0198008 A1
(43) Pub. Date: Jul. 12, 2018

(54) PHOTOVOLTAIC STRUCTURES WITH SEGMENTED BUSBARS FOR INCREASED THERMAL CYCLING RELIABILITY

(71) Applicant: SolarCity Corporation, San Mateo, CA (US)

(72) Inventors: Scott Tripp, Milpitas, CA (US); Milan Padilla, Mountain View, CA (US)

(73) Assignee: SolarCity Corporation, San Mateo, CA (US)

(21) Appl. No.: 15/400,874

(22) Filed: Jan. 6, 2017

(51) Int. Cl. H01L 31/0224; H01L 31/02; H01L 31/0352; H01L 31/05

(52) U.S. Cl. CPC H01L 31/022433; H01L 31/0201; H01L 31/022466; H01L 31/0512; H01L 31/0516; H01L 31/0508; H01L 31/035209

(57) ABSTRACT

One embodiment can provide an electrode grid of a photovoltaic structure. The electrode grid can include a plurality of finger lines and a busbar coupled to the finger lines. The busbar can include one or more stress-release structures, thereby reducing stress caused by thermal expansion mismatch between the busbar and underlying layers of the photovoltaic structure.

### FIELD OF THE INVENTION

This is generally related to photovoltaic structures. More specifically, this is related to the busbar design of a photovoltaic structure. The novel busbar design can reduce thermal stress exerted on the bond between the busbar and the underlying structure.

### Definitions

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

Advances in photovoltaic technology, which are used to make solar panels, have helped solar energy gain mass appeal among those wishing to reduce their carbon footprint and decrease their monthly energy costs. However, the panels are typically fabricated manually, which is a time-consuming and error-prone process that makes it costly to mass-produce reliable solar panels.

Solar panels typically include one or more strings of complete photovoltaic structures. Adjacent photovoltaic structures in a string may overlap one another in a cascading arrangement. For example, continuous strings of photovoltaic structures that form a solar panel are described in U.S. patent application Ser. No. 14/510,008, Attorney Docket No. P67-2, filed Oct. 8, 2014, and entitled “Module Fabrication of Solar Cells with Low Resistivity Electrodes,” the disclosure of which is incorporated herein by reference in its entirety. Producing solar panels with a cascaded cell arrangement can reduce the resistance due to inter-connections between the cells, and can increase the number of photovoltaic structures that can fit into a solar panel.

Fabrications of such cascaded panels can involve overlapping edges of adjacent cells in such a way that the electrodes (busbars) on opposite sides of the overlapped cells are in contact to establish an electrical connection. This process is repeated for a number of successive cells until one string of cascaded cells is created. A number of strings are then coupled to each other (either in series or in parallel) and placed in a protective frame. To further reduce internal resistance of the entire panel and to ensure that the manufactured panel is compatible with conventional panels, one form of the cascaded panel (as described in the aforementioned patent application) can include a series of solar cell strips created by dividing complete solar cells into smaller pieces (i.e., the strips). These smaller strips can then be cascaded (edge overlapped) to form a string. Proper mechanical bonding and electrical coupling between busbars of adjacent strips are needed.

### SUMMARY

One embodiment can provide an electrode grid of a photovoltaic structure. The electrode grid can include a plurality of finger lines and a busbar coupled to the finger lines. The busbar can include one or more stress-release structures, thereby reducing stress caused by thermal expansion mismatch between the busbar and underlying layers of the photovoltaic structure.

In some embodiments, the busbar can include segments of a metallic strip, and a respective stress-release structure can include a gap positioned between two adjacent segments of the metallic strip.

In further embodiments, the two adjacent segments can be electrically coupled to each other by a metallic line having a width smaller than a width of the metallic strip.

In some embodiments, the busbar can include a continuous metallic strip having a varying width.

In further embodiments, the width of the continuous metallic strip can be periodically modulated.

In some embodiments, the busbar can include a continuous zigzag-shaped metallic strip along a length of the photovoltaic structure.

In some embodiments, both of the finger lines and busbar can include an electroplated Cu layer.

One embodiment can provide a solar cell. The photovoltaic structure can include a multilayer photovoltaic structure, a first metallic grid positioned on a first surface of the photovoltaic structure, and a second metallic grid positioned on a second surface of the photovoltaic structure. The first metallic grid can include a first busbar; and the second metallic grid can include a second busbar. The first and second busbars each can include one or more stress-release structures, thereby reducing stress caused by thermal expansion mismatch between the busbars and the multilayer photovoltaic structure.

One embodiment can provide a photovoltaic module, which can include a plurality of photovoltaic structures. A respective photovoltaic structure can include a multilayer structure, a first metallic grid comprising a first edge busbar positioned on a first surface of the multilayer structure, and a second metallic grid comprising a second edge busbar positioned on a second surface of the multilayer structure. The first and second edge busbars are positioned on opposite edges and opposite sides of the photovoltaic structure. The photovoltaic structures can be arranged in such a way that the first edge busbar of a first photovoltaic structure overlaps with the second edge busbar of an adjacent photovoltaic structure, with conductive paste positioned between the first and second edge busbars. The first and second edge busbars each can include one or more stress-release structures, thereby reducing stress caused by thermal expansion mismatch between the busbars and the conductive paste.

### BRIEF DESCRIPTION OF THE FIGURES

FIG. 1A shows an exemplary grid pattern on the front surface of a photovoltaic structure.

FIG. 1B shows an exemplary grid pattern on the back surface of a photovoltaic structure.

FIG. 2A shows a string of cascaded strips.

FIG. 2B shows a side view of the string of cascaded strips.

FIG. 3A shows an exemplary grid pattern on the front surface of a photovoltaic structure, according to one embodiment.

FIG. 3B shows the amplified view of a section of the front side metallic grid, according to one embodiment.

FIG. 4A shows an exemplary grid pattern on the back surface of a photovoltaic structure, according to one embodiment.

FIG. 4B shows the amplified view of a section of the back side metallic grid, according to one embodiment.

FIG. 4C shows the partial cross-sectional view of a segmented busbar, according to an embodiment.

FIG. 5A shows an exemplary grid pattern on the front surface of a photovoltaic structure, according to one embodiment.

FIG. 5B shows an exemplary grid pattern on the back surface of a photovoltaic structure, according to one embodiment.

FIGS. 6A-6D each show a partial view of an exemplary busbar, according to one embodiment.

FIG. 7A shows a partial view of an exemplary busbar, according to one embodiment.

FIG. 7B shows a partial view of an exemplary busbar, according to one embodiment.

FIG. 8A shows the cross-sectional view of the overlapped edge busbars with conductive paste applied, according to an embodiment.

FIG. 8B shows the cross-sectional view of the overlapped edge busbars with conductive paste applied, according to an embodiment.

FIG. 9A shows a partial view of an exemplary grid with conductive paste applied, according to one embodiment.

FIG. 9B shows the cross-sectional view of two overlapped edge busbars with conductive paste applied, according to an embodiment.

FIG. 10 shows an exemplary solar module fabrication process, according to an embodiment of the invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the invention is not limited to the embodiments shown, but is to be accorded the widest scope consistent with the principles and features disclosed herein.

### Overview

Embodiments of the invention can provide a novel busbar design for photovoltaic structures. More specifically, the claimed invention can provide a solution for the bond failure problem facing a cascaded solar module, which includes partially overlapped strips bonded by conductive paste. To prevent the accumulation of stress at the metal-paste interface, the edge busbars can be specially designed to have one or more built-in stress-release structures. In some embodiments, an edge busbar can be segmented with air gaps separating adjacent segments. The air gaps can act as stress-release structures to release thermal stresses exerted on the metal-paste interface or within the body of the conductive paste. In some embodiments, an edge busbar can have a varying width, and the portions with a narrower width can function as the built-in stress-release structures. In alternative embodiments, an edge busbar can include a zigzagged metallic strip, and adjacent portions of the strip aligning along different directions together can form a built-in stress-release structure, because thermal stresses exerted on them can partially cancel each other out.

### Solar Panel Based on Cascaded Strips

As described in U.S. patent application Ser. No. 14/563,867, a solar panel can have multiple (e.g., three) strings, each string including cascaded strips, connected in parallel. Such a multiple-parallel-string panel configuration provides the same output voltage with a reduced internal resistance. In general, a cell can be divided into n strips, and a panel can contain n strings. Each string can have the same number of strips as the number of regular photovoltaic structures in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel, while the panel's total internal resistance can be 1/n of the resistance of a string. Therefore, in general, a greater n can lead to a lower total internal resistance and, hence, more power extracted from the panel. However, a tradeoff is that as n increases, the number of connections required to interconnect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance, the greater n might need to be to effectively reduce the panel's overall internal resistance. Therefore, the type of electrode can dictate the number of strips. For example, conventional silver-paste or aluminum-based electrodes typically cannot produce ideal resistance between the electrode and underlying photovoltaic structure. As a result, such electrodes may require n to be greater than four. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n can be selected to be three, which is less than the n value generally needed for cells with silver-paste electrodes or other types of electrodes. Correspondingly, two grooves can be scribed on a single cell to allow the cell to be divided into three strips.

In addition to lower contact resistance, electroplated copper electrodes can also offer better tolerance to microcracks, which may occur during a cleaving process. Such microcracks might adversely impact silver-paste-electrode cells. Plated-copper electrodes, on the other hand, can preserve the conductivity across the cell surface even if there are microcracks in the photovoltaic structure. The copper electrode's higher tolerance for microcracks can allow one to use thinner silicon wafers to manufacture cells. As a result, the grooves to be scribed on a cell can be shallower than the grooves scribed on a thicker wafer, which in turn can help increase the throughput of the scribing process. More details on using copper plating to form low-resistance electrodes on a photovoltaic structure are provided in U.S. patent application Ser. No. 13/220,532, Attorney Docket No. P59-1NUS, entitled “SOLAR CELL WITH ELECTROPLATED GRID,” filed Aug. 29, 2011, the disclosure of which is incorporated herein by reference in its entirety.

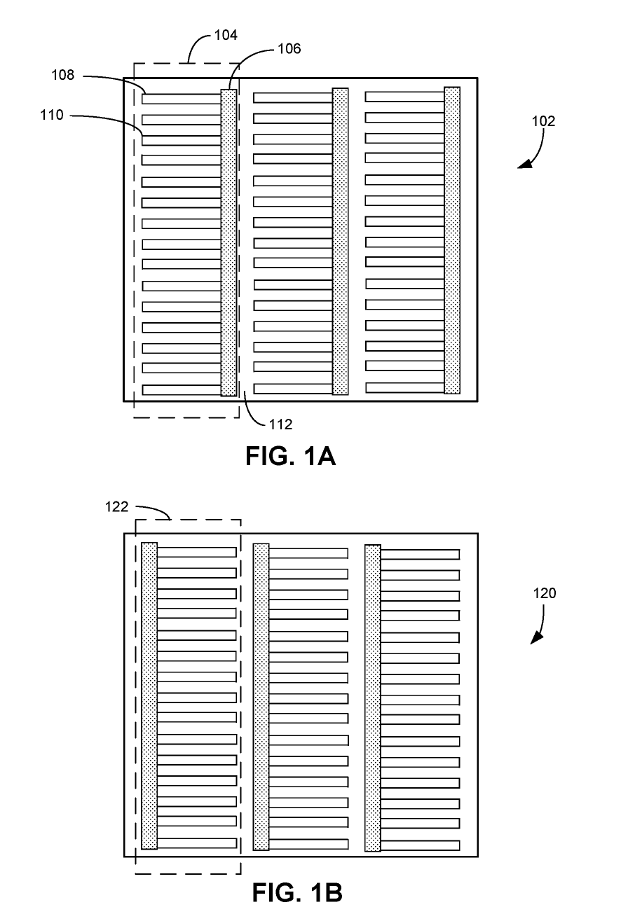

FIG. 1A shows an exemplary grid pattern on the front surface of a photovoltaic structure. In the example shown in FIG. 1A, grid 102 can include three sub-grids, such as sub-grid 104. This three sub-grid configuration can allow the photovoltaic structure to be divided into three strips. To enable cascading, each sub-grid can have an edge busbar, which can be located either at or near the edge. In the example shown in FIG. 1A, each sub-grid can include an edge busbar (“edge” here refers to the edge of a respective strip) running along the longer edge of the corresponding strip and a plurality of parallel finger lines running in a direction parallel to the shorter edge of the strip. For example, sub-grid 104 can include edge busbar 106, and a plurality of finger lines, such as finger lines 108 and 110. To facilitate the subsequent laser-assisted scribe-and-cleave process, a predefined blank space (i.e., space not covered by electrodes) can be inserted between the adjacent sub-grids. For example, blank space 112 can be defined to separate sub-grid 104 from its adjacent sub-grid. In some embodiments, the width of the blank space, such as blank space 112, can be between 0.1 mm and 5 mm, preferably between 0.5 mm and 2 mm. There is a tradeoff between a wider space that leads to a more tolerant scribing operation and a narrower space that leads to more effective current collection. In a further embodiment, the width of such a blank space can be approximately 1 mm.

FIG. 1B shows an exemplary grid pattern on the back surface of a photovoltaic structure. When showing the back surface, for illustration purposes, the photovoltaic structure is assumed to be transparent. The grid patterns on the front and back surfaces of the photovoltaic structure are viewed from the same viewing point. In the example shown in FIG. 1B, back grid 120 can include three sub-grids, such as sub-grid 122. To enable cascaded and bifacial operation, the back sub-grid may correspond to the front sub-grid. More specifically, the back edge busbar can be located at the opposite edge of the frontside edge busbar. In the examples shown in FIGS. 1A and 1B, the front and back sub-grids can have similar patterns except that the front and back edge busbars are located adjacent to opposite edges of the strip. In addition, locations of the blank spaces in back conductive grid 120 can correspond to locations of the blank spaces in front conductive grid 102, such that the grid lines do not interfere with the subsequent scribe-and-cleave process. In practice, the finger line patterns on the front and back sides of the photovoltaic structure may be the same or different.

In the examples shown in FIGS. 1A and 1B, the finger line patterns can include continuous, non-broken loops. For example, as shown in FIG. 1A, finger lines 108 and 110 can both include connected loops. This type of “looped” finger line pattern can reduce the likelihood of the finger lines peeling away from the photovoltaic structure after long use. Optionally, the sections where parallel lines are joined can be wider than the rest of the finger lines to provide more durability and prevent peeling. Patterns other than the one shown in FIGS. 1A and 1B, such as un-looped straight lines or loops with different shapes, are also possible.

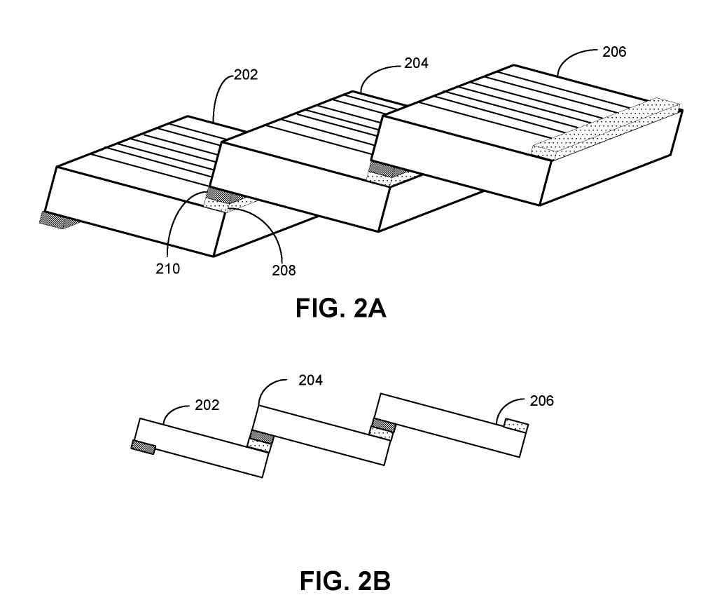

To form a cascaded string, cells or strips (e.g., as a result of a scribing-and-cleaving process applied to a regular square cell) can be cascaded with their edges overlapped. FIG. 2A shows a string of cascaded strips. In FIG. 2A, strips 202, 204, and 206 can be stacked in such a way that strip 206 can partially overlap adjacent strip 204, which can also partially overlap (on an opposite edge) strip 202. Such a string of strips can form a pattern that is similar to roof shingles. Each strip can include top and bottom edge busbars located at opposite edges of the top and bottom surfaces, respectively. Strips 202 and 204 may be coupled to each other via an edge busbar 208 located at the top surface of strip 202 and an edge busbar 210 located at the bottom surface of strip 204. To establish electrical coupling, strips 202 and 204 can be placed in such a way that bottom edge busbar 210 is placed on top of and in direct contact with top edge busbar 208.

FIG. 2B shows a side view of the string of cascaded strips. In the example shown in FIGS. 2A and 2B, the strips can be part of a 6-inch square photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) can be placed at the very edge of the strip (as shown in FIGS. 2A and 2B). The same cascaded pattern can extend along an entire row of strips to form a serially connected string.

### Busbar Designs for Reducing Thermal Stress

When forming a solar panel, adjacent strips may be bonded together via edge busbars. Such bonding can be important to ensure that the electrical connections are well-maintained when the solar panel is put into service. One option for bonding the metallic busbars can include soldering. For example, the surface of the edge busbars may be coated with a thin layer of Sn. During a subsequent lamination process, heat and pressure can be applied to cure sealant material between photovoltaic structures and the front and back covers of the solar panel. The same heat and pressure can also solder together the edge busbars that are in contact, such as edge busbars 208 and 210. However, the rigid bonding between the soldered contacts may lead to cracking of the thin strips. Moreover, when in service solar panels often experience many temperature cycles, and the thermal mismatch between the metal and the semiconductor may create structural stress that can lead to fracturing. Note that the source of the interfacial stress between the bonding material and the busbar might not only be caused by thermal cycling, but can also be a result of the manufacturing process. For example, if the bonding material (such as a conductive adhesive) is flash-cured at a high temperature (e.g., >120° C.), the stress-free state would occur at this curing temperature. When the bonding cools to room temperature, however, the bonding interface is no longer in the stress-free state. Hence, the interface would remain in an under-stress state during normal operation conditions, and would be subject to more stress as the temperature drops lower (e.g., at night or during winter). The designs described herein can mitigate the stress caused by both aforementioned sources.

To reduce the thermal or mechanical stress, it can be preferable to use a bonding mechanism that is sufficiently flexible and can withstand many temperature cycles. One way to do so is to bond the strips using flexible adhesive that is electrically conductive. For example, adhesive (or paste) can be applied on the surface of top edge busbar 208 of strip 202 (shown in FIG. 2A). When strip 204 is placed to partially overlap with strip 202, bottom edge busbar 210 can be bonded to top edge busbar 208 by the adhesive, which can be cured at an elevated temperature. Different types of conductive adhesive or paste can be used to bond the busbars. In one embodiment, the conductive paste can include a conductive metallic core surrounded by a resin. When the paste is applied to a busbar, the metallic core establishes an electrical connection with the busbar while the resin that surrounds the metallic core functions as an adhesive. In another embodiment, the conductive adhesive may be in the form of a resin that includes a number of suspended conductive particles, such as Ag or Cu particles. The conductive particles may be coated with a protective layer. When the paste is thermally cured, the protective layer can evaporate to enable electrical conductivity between the conductive particles suspended inside the resin.

Although the conductive paste can provide relatively flexible bonding, the coefficient of thermal expansion (CTE) mismatch between the metallic busbars (e.g., Cu busbars), the conductive paste, and the silicon wafer can cause a number of problems, including wafer warping, adhesive failure, and breakage of cured conductive paste. Considering that a solar panel experiences a great number of temperature cycles during its service life, a small failure point can propagate along the bond line or inside the cured paste, causing failures on a larger scale.

In order to mitigate the thermal stress exerted on the bond, the shape of the metallic busbar can be specially designed. More specifically, instead of being a rectangular strip that may expand or contract along a continuous straight line, causing accumulation of thermal stress, the busbar can have a specially designed shape that can prevent the buildup of the thermal stress. If the maximum thermal stress accumulated within the bond is kept below a threshold value, even if a failure point occurs inside the cured paste, it is less likely to propagate.

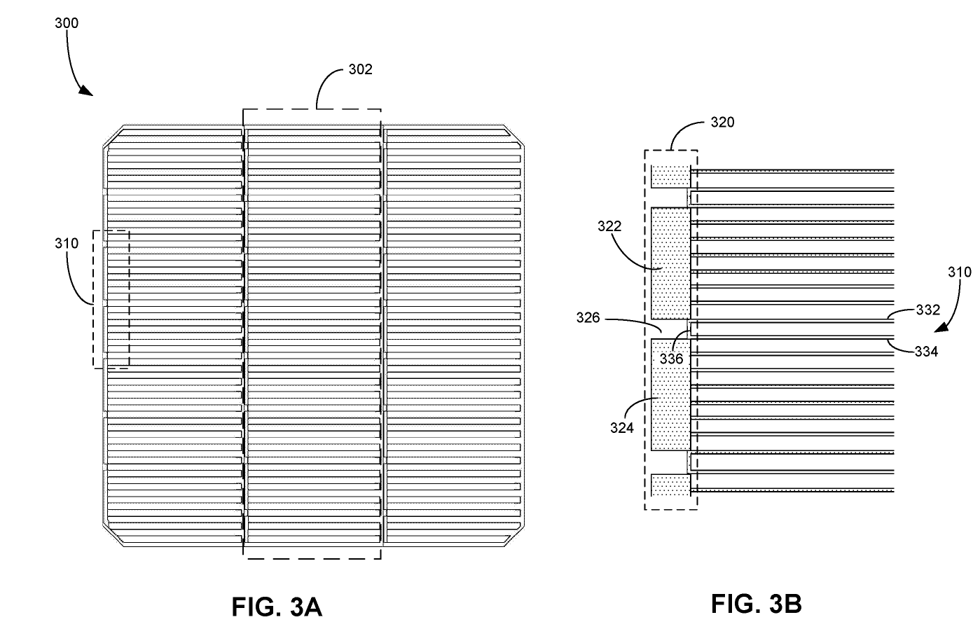

In some embodiments, instead of a continuous metallic strip, the busbar can include multiple segmented sections with air gaps in between. The air gaps can release the thermal stress at the interface between the metallic busbar and the conductive paste that bonds the metallic busbar to the silicon substrate. FIG. 3A shows an exemplary grid pattern on the front surface of a photovoltaic structure, according to one embodiment. For bifacial operation, the front surface of the photovoltaic structure faces the majority of the incoming light. Similar to grid 102 shown in FIG. 1A, grid 300 shown in FIG. 3A can include a number of sub-grids, such as sub-grid 302. Each sub-grid can include an edge busbar and a number of finger lines. Instead of a continuous strip, the edge busbar can include a number of segments that are separated from each other by air gaps.

FIG. 3B shows the amplified view of a section of the front side metallic grid, according to one embodiment. More specifically, FIG. 3B shows the amplified view of section 310, which is part of grid 300 shown in FIG. 3A. Section 310 can include a partial view of edge busbar 320 along with a number of finger lines coupled to edge busbar 320. In FIG. 3B, edge busbar 320 can include a number of segments separated by air gaps. For example, segments 322 and 324 of busbar 320 are separated by air gap 326. To ensure the metal continuity, which is essential in preventing peeling off of the finger lines, finger lines coupled to edges of adjacent busbar segments can be part of a continuous loop. For example, finger line 332, which is coupled to the edge of busbar segment 322, and finger line 334, which is coupled to the edge of busbar segment 324, are coupled to each other by short metal strip 336, forming a continuous loop. One can also say that short metal strip 336 couples together, both mechanically and electrically, segments 322 and 324. The electrical coupling between adjacent segments of busbar 320 can ensure continuous flow of electricity inside the busbar.

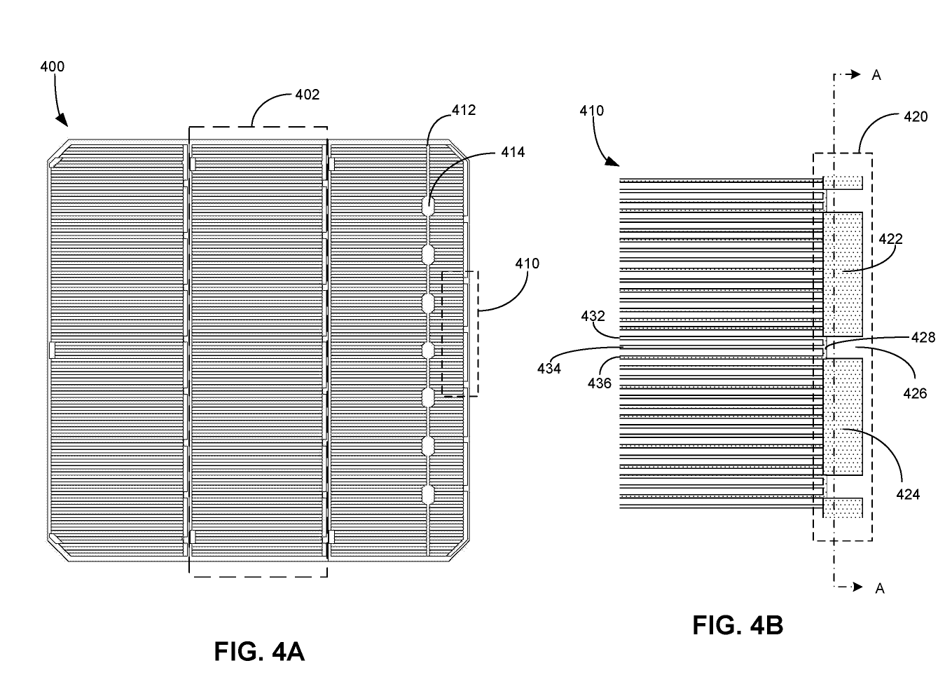

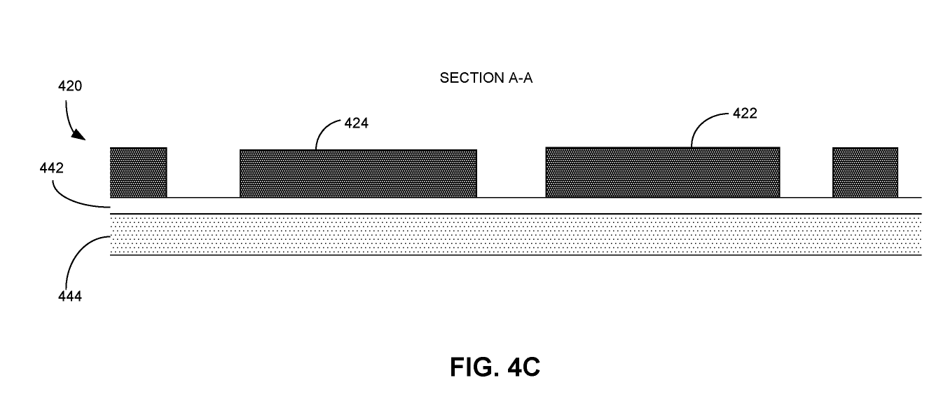

FIG. 4A shows an exemplary grid pattern on the back surface of a photovoltaic structure, according to one embodiment. Similar to grid 300, grid 400 shown in FIG. 4A can include a number of sub-grids, such as sub-grid 402. Each sub-grid can include an edge busbar and a number of finger lines, and the edge busbar can include a number of segments that are separated from each other by air gaps. As one can see, grid 400 is very similar to grid 300, except that finger lines of grid 400 have a much smaller pitch than those of grid 300. The back side of a solar panel typically absorbs indirect sunlight, which can include reflected, deflected, and diffused sunlight from various surfaces surrounding the panel. A denser grid can be advantageous due to its increased current-collection efficiency.

In addition to an edge busbar, one or more sub-grids of grid 400 can include an additional busbar, such as additional busbar 412. This additional busbar can include one or more contact pads (e.g., contact pad 412) that can facilitate electrical connections to the photovoltaic structure, in the event of the edge busbars of the photovoltaic structure being inaccessible. Detailed descriptions of the additional busbar and contact pads can be found in U.S. patent application Ser. No. 14/831,767, Attorney Docket No. P142-1NUS, entitled “PHOTOVOLTAIC ELECTRODE DESIGN WITH CONTACT PADS FOR CASCADED APPLICATION,” filed Aug. 20, 2015, the disclosure of which is incorporated herein by reference in its entirety.

FIG. 4B shows the amplified view of a section of the back side metallic grid, according to one embodiment. More specifically, FIG. 4B shows the amplified view of section 410, which is part of grid 400 shown in FIG. 4A. Section 410 can include a partial view of edge busbar 420 along with a number of finger lines coupled to edge busbar 420. In FIG. 4B, edge busbar 420 can include a number of segments separated by air gaps. For example, segments 422 and 424 of busbar 420 are separated by air gap 426. A short metallic strip can be used to couple adjacent segments. For example, metallic strip 428 can be used to couple adjacent segments 422 and 424. In addition to electrically coupling adjacent segments of busbar 420, metallic strip 428 can also couple together finger lines (e.g., finger lines 432, 434, and 436) that may otherwise have open ends. As discussed previously, open finger lines are more likely to peel off.

FIG. 4C shows the partial cross-sectional view of a segmented busbar, according to an embodiment. More specifically, FIG. 4C shows the sectional view along cut plane A-A, indicated by dashed arrows shown in FIG. 4B. Plane A-A cuts through the middle of busbar 420 in a direction that is along the length of the busbar. FIG. 4C shows the profile of busbar 420 as well as the layer structure of the photovoltaic structure, which can include, in addition to the metallic grid, transparent conductive oxide (TCO) layer 442, and photovoltaic body 444. Photovoltaic body 444 often can include a Si base layer and an emitter layer. Photovoltaic body 444 can optionally include other layers, such as quantum-tunneling barrier (QTB) layers and surface field layers, which can enhance the energy-conversion efficiency of the photovoltaic structure. The scope of the instant application cannot be limited by the specific structure of photovoltaic body 444.

In some embodiments, the segments (e.g., segments 322, 324, 422 and 424) of the busbars can be of the same size. In the examples shown in FIGS. 3A and 4A, each segment has the same width as that of the conventional busbar, and can also have the same length. The length of each segment can be between 10 and 20 mm. Compared to a conventional continuous busbar, which can be about 150 mm long for 6-inch wafers, the shorter segments in the segmented busbar each can experience less thermal stress. More specifically, the empty space between adjacent busbar segments allows any thermal stress built within each segment to be released. In some embodiments, the empty space between adjacent segments can be between 1 and 5 mm. Larger spacing between segments can release more thermal stress, whereas smaller spacing between the metallic segments can provide better current-collection efficiency.

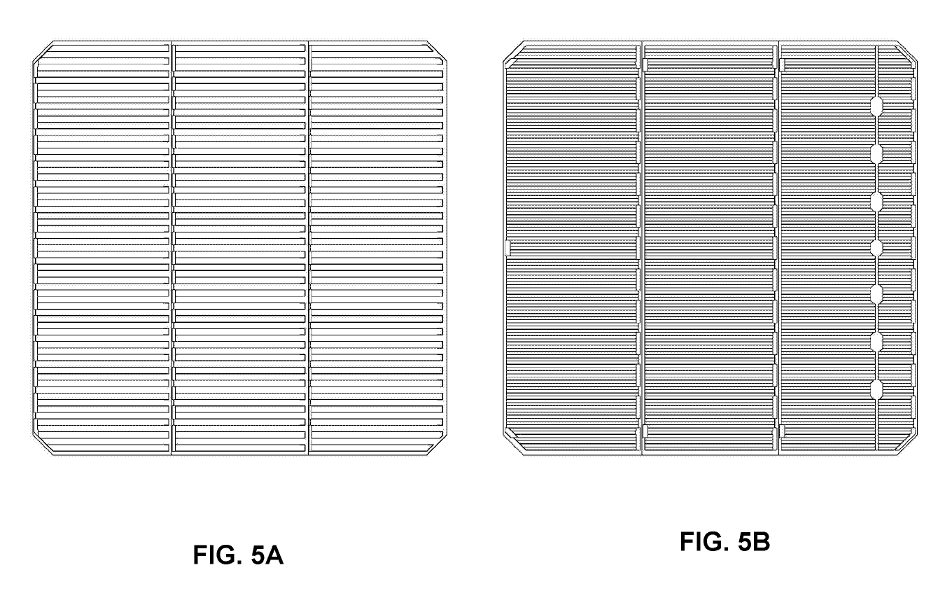

In the examples shown in FIGS. 3A and 4A, each busbar has a few (e.g., fewer than 10) segments and the length of each segment is much larger than the spacing. In alternative embodiments, a busbar can have many more (e.g., more than 10) segments, with the segment length being comparable to the size of the spacing. FIG. 5A shows an exemplary grid pattern on the front surface of a photovoltaic structure, according to one embodiment. FIG. 5B shows an exemplary grid pattern on the back surface of a photovoltaic structure, according to one embodiment. In the examples shown in FIGS. 5A and 5B, each busbar is divided into 15 segments, and the length of each segment can be less than 10 mm. The shorter busbar segments typically accumulate smaller amounts of thermal stress than longer busbar segments. However, decreasing the length of each segment can increase the number of segments of each busbar, thus the lithographic complexity. Similar to the examples shown in FIGS. 3A and 4A, the finger lines in FIGS. 5A and 5B are looped without open ends. However, in the examples shown in FIGS. 5A and 5B, the short metallic strip connecting finger lines at the edge of adjacent busbar segments is positioned at the midpoint, instead of the edge of the busbar segments. The width of the short metal strip can be similar to the width of the finger lines and much smaller than the width of the busbar segments, resulting in empty space existing between the metal segments. The empty space allows any thermal stress built along the length of the segments to be released. The short metal strip can be placed at other locations (e.g., at the busbar edge away from the finger lines) as long as the busbar segments are connected and the finger lines are looped. In alternative embodiments, there may not be a short strip connecting adjacent segments of the busbar and the finger lines are designed to all intersect with busbar segments without open ends.

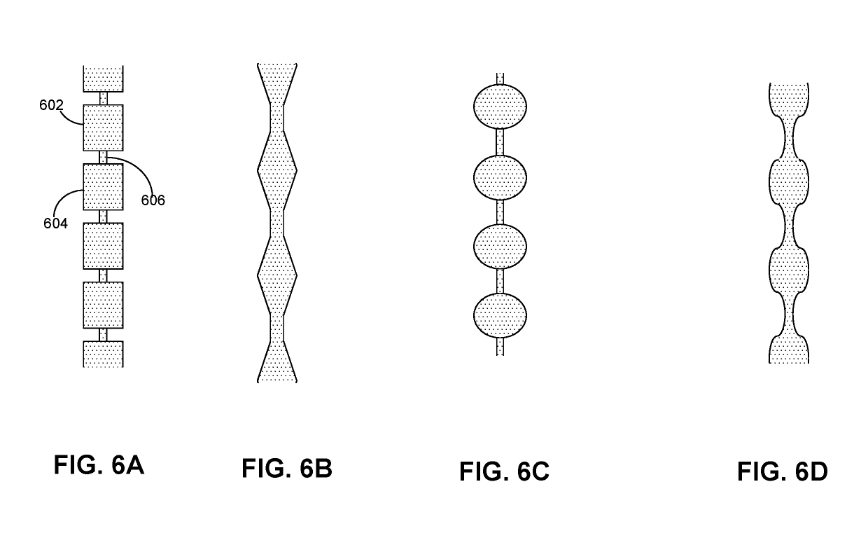

FIG. 6A shows a partial view of an exemplary busbar, according to one embodiment. The busbar shown in FIG. 6A is similar to the busbars shown in FIGS. 5A and 5B. More specifically, in FIG. 6A, adjacent segments of the busbar are connected to each other by a short metal strip positioned at the midpoint of the segment edge. For example, segments 602 and 604 are connected to each other by short metal strip 606, which is positioned at the midpoint of the edges of segments 602 and 604. The width of short metal strip 606 is much smaller than the width of busbar segments 602 and 604, thus allowing thermal stress built within each busbar segment to be released. For example, the width of busbar segments 602 and 604 can be between 1 and 3 mm, and the width of short metal strip 606 can be between 200 and 500 microns.

The busbar can also have different shapes as long as it can include a structure that can release thermal stress before it exceeds a threshold that can possibly cause mechanical failure at the metal-paste boundary or within the paste. FIG. 6B shows a partial view of an exemplary busbar, according to one embodiment. In FIG. 6B, each busbar segment can be tapered; the narrower portions of the busbar can act as built-in thermal-stress-release structures. The tapered structure can prevent current crowding at the intersection between a busbar segment and the narrow metal strip. FIG. 6C shows a partial view of an exemplary busbar, according to one embodiment. The busbar shown in FIG. 6C is similar to the one shown in FIG. 6A and has multiple segments that are connected to each other by shorter and narrower metallic strips. However, in FIG. 6C, instead of being rectangular, the busbar segments can have a circular shape. Alternatively, the busbar segments can also be shaped like ovals. FIG. 6D shows a partial view of an exemplary busbar, according to one embodiment. In the example shown in FIG. 6D, the outline of the entire busbar only includes curves. The elimination of sharp edges can also prevent current crowding. Similar to the structures shown in FIGS. 6A-6C, the busbar shown in FIG. 6D includes wider metal portions connected by narrower portions. The narrower metal portions can function as built-in thermal-stress-release structures.

In the examples shown in FIGS. 6A-6D, the busbars are either segmented or have varying widths. In FIGS. 6A and 6C, segments of the edge busbar can be connected by thinner metallic lines, with air gaps between segments functioning as a built-in thermal-stress-release structures that can release any thermal stress accumulated within the segments. Similarly, in FIGS. 6B and 6D, the width of the busbar can be periodically modulated, resulting in the busbar to have narrower and wider portions. The narrower portions of the busbar can function as built-in thermal-stress-release structures that can release any thermal stress accumulated within the wider portions of the busbar. The same principle can be used to design busbars having shapes that are different from the ones shown in FIGS. 6A-6D. For example, the busbar segments can have different regular or irregular shapes, such as trapezoid, rhombus, triangle, oval, half circle, etc. Moreover, instead of having a repeatable pattern (e.g., having equal-length segments or periodic width variations), the shape of the busbar can also be randomly designed, as long as the busbar includes thermal-stress-release structures inserted in locations where accumulated thermal stress being less than a predetermined threshold. Having a busbar segment that is too long may still result in a bond failure caused by too much stress within the segment.

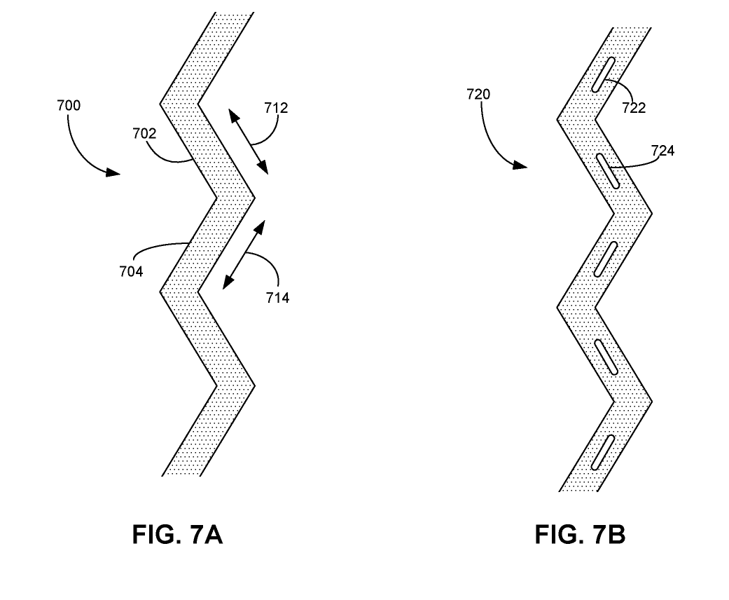

In addition to achieving thermal stress relief by varying the width of the busbar, in some embodiments, the busbar may have a uniform width but can have sections extending in different directions. FIG. 7A shows a partial view of an exemplary busbar, according to one embodiment. In FIG. 7A, busbar 700 can be a zigzagged metallic strip having a uniform width. Different sections of busbar 700 can extend along different directions. Therefore, when the temperature changes, different sections of busbar 700 can expand or contract along different directions. For example, when the temperature rises, section 702 can expand along the direction shown by arrow 712, and section 704 can expand along the direction shown by arrow 714. Because they are expanding toward different directions, the thermal stress caused by their expansion may partially cancel each other out. By laying the busbar along a zigzagged path, one can release the thermal stress without the need to vary the width of the busbar, and a busbar with a uniform width can have higher current-collection efficiency. In the example shown in FIG. 7A, the busbar sections that are not on a straight line but forming an obtuse angle together function as the thermal-stress-release structure. Although the thermal-stress-release structure shown in FIG. 7A takes a form that is different from the ones shown in FIGS. 6A-6D, they perform the same function, i.e., releasing possible thermal stress along the metal-paste boundary.

Other stress-release structures are also possible. FIG. 7B shows a partial view of an exemplary busbar, according to one embodiment. Busbar 720 shown in FIG. 7B can be similar to busbar 700 shown in FIG. 7A and can include a zigzagged metal strip. In addition, busbar 720 can include a number of voids embedded within the metal strip, such as voids 722 and 724, which can further release thermal stress introduced by the CTE mismatch. In addition, it is also possible to combine the structures shown in FIGS. 6A-6D with the ones shown in FIGS. 7A-7B. For example, it is possible to have a segmented and zigzagged busbar, or to vary the width of the zigzagged busbar.

### Module Fabrication

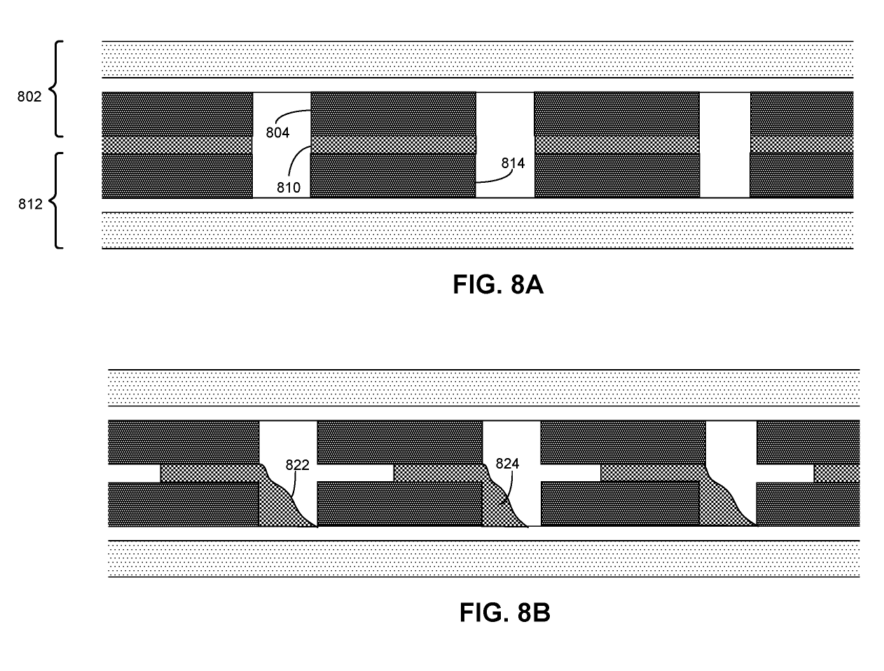

As discussed in the previous section, a solar cell string can be formed by bonding a number of strips. More specifically, adjacent strips can be arranged such that they overlap at the edge, and the opposite edge busbars of the adjacent strip can overlap and be bonded together by conductive paste. FIG. 8A shows the cross-sectional view of the overlapped edge busbars with conductive paste applied, according to an embodiment. More specifically, FIG. 8A shows an edge busbar of strip 802 overlapping with an edge busbar of strip 812, each busbar segment of strip 802 overlapping with a busbar segment of strip 812. For example, busbar segment 804 of strip 802 is substantially aligned to and overlapped with busbar segment 814 of strip 812 with cured conductive paste 810 positioned between segments 804 and 814.

FIG. 8A shows an ideal situation where the blobs or droplets of conductive paste are deposited onto each busbar segment. Hence, the cured paste can be perfectly aligned to the overlapping busbar segments. In practice, portions of the conductive paste may be deposited at the empty space between the two adjacent segments of a busbar and may fail to bond the two strips. FIG. 8B shows the cross-sectional view of the overlapped edge busbars with conductive paste applied, according to an embodiment. In the scenario shown in FIG. 8B, when blobs of conductive paste were deposited onto a segmented busbar, they were misaligned with the busbar segments, resulting in portions (e.g., portions 822 and 824) of the conductive paste falling within the empty space between busbar segments. These portions of the conductive paste do not participate in the bonding between the two busbars, resulting in a weaker bond between the overlapping busbars. To ensure sufficient bonding between the busbars, one needs to make sure that the conductive paste can be properly deposited onto the surface of the busbar segments, instead of inside the voids between segments.

Various techniques can be used to deposit the conductive paste, including manual paste application and automatic paste application. For large-scale manufacturing of solar panels, an automated paste-dispensing system can be used to precisely dispense the paste onto the busbars. A detailed description of an automated paste-dispensing system can be found in U.S. patent application Ser. No. 14/866,806, Attorney Docket No. P103-6NUS, entitled “METHODS AND SYSTEMS FOR PRECISION APPLICATION OF CONDUCTIVE ADHESIVE PASTE ON PHOTOVOLTAIC STRUCTURES,” filed Sep. 25, 2015, the disclosure of which is incorporated herein by reference in its entirety. During operation, the automated paste-dispensing system can be programmed to ensure that the conductive paste is only deposited onto the surface of the busbar segments. For example, the moving speed of the paste dispenser relative to the solar strips can be carefully controlled, along with the timing of the releasing of the paste droplets.

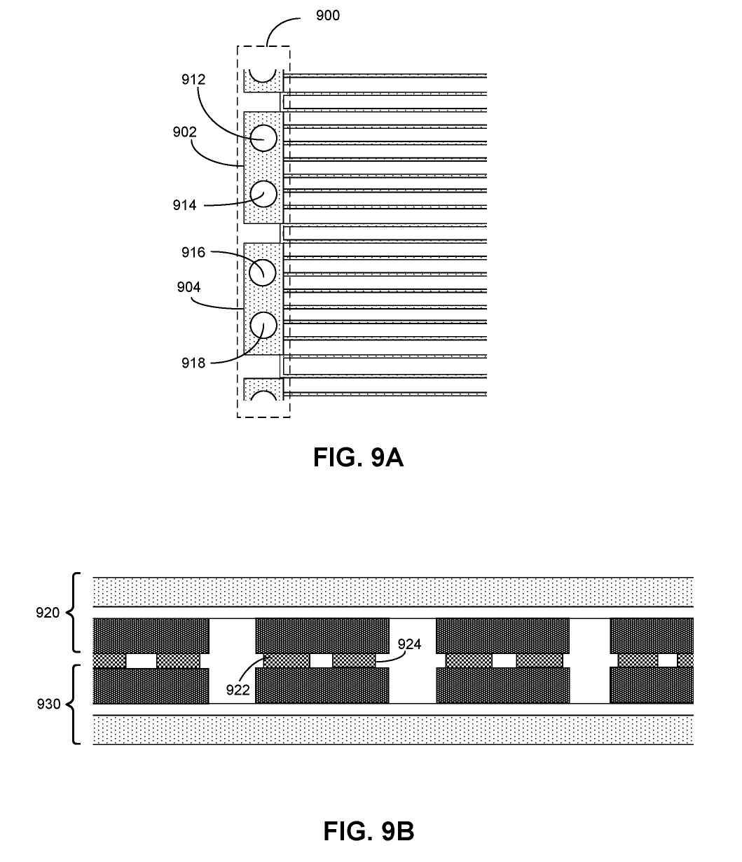

In addition to the example shown in FIG. 8A where each busbar segment is continuously covered by conductive paste, it is also possible to deposit discrete droplets of conductive paste onto the surface of the segments. FIG. 9A shows a partial view of an exemplary grid with conductive paste applied, according to one embodiment. In FIG. 9A, busbar 900 can include a number of segments (e.g., segments 902 and 904), and a number of conductive paste droplets can be deposited onto the surface of each busbar segment. For example, droplets 912 and 914 can be deposited onto segment 902, and droplets 916 and 918 can be deposited onto segment 904. FIG. 9B shows the cross-sectional view of two overlapped edge busbars with conductive paste applied, according to an embodiment. In FIG. 9B, busbar segments of strip 920 overlap with busbar segments of strip 930, with droplets of conductive paste sandwiched between the overlapped busbar segments. In some embodiments, after curing, the conductive paste droplets remain separated from each other. For example, the cured paste droplets 922 and 924 are separated from each other. The segregation between the paste droplets prevents the propagation of a local crack. More specifically, even if a crack occurs within a droplet of cured paste due to thermal stress, this crack cannot propagate to other parts of the cured paste. This is especially important for the zigzagged busbars that include continuous metallic strips. If the surface of a zigzagged busbar is completely covered with cured conductive paste, a small defect or breakage within the paste may propagate within the body of the continuous paste, leading to a larger scale of paste failure. Applying the paste as separate droplets prevents the propagation of the cracks. In some embodiments, the distance between the cured paste droplets can be controlled to be between 0.5 and 2 mm.

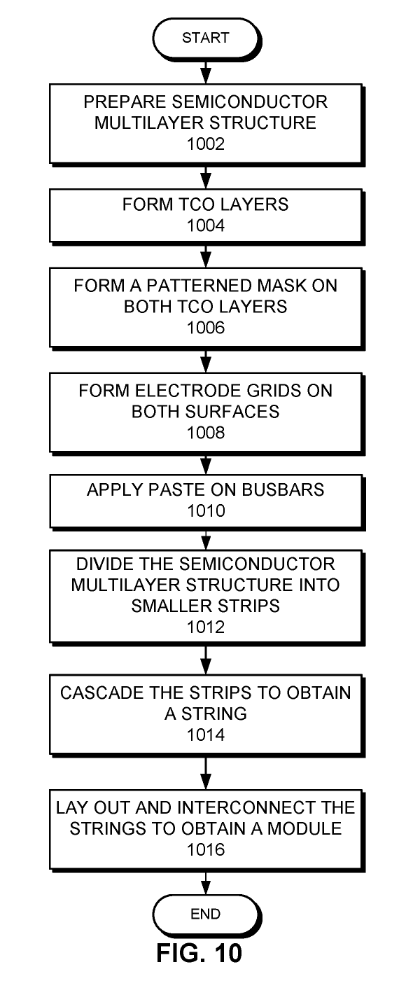

The fabrication process for the photovoltaic structure with the specially designed busbars can be similar to the fabrication process used for forming regular photovoltaic structures, except that a special mask that defines busbars with one or more thermal-stress-release structures can be used instead of a conventional mask that defined a rectangular-shaped busbar. FIG. 10 shows an exemplary solar module fabrication process, according to an embodiment of the invention. During fabrication, a semiconductor multilayer structure that includes a base layer, an emitter layer, and a surface field layer can be prepared (operation 1002). The multilayer structure can also optionally include a passivation layer (e.g., a quantum tunneling barrier layer) on one or both sides of the base layer. A TCO layer can be formed on one or both sides of the multilayer structure (operation 1004). The TCO layer can be formed using a low temperature (less than 200° C.) PVD process and can include Ti- and/or Ta-doped In₂O₃. For bifacial photovoltaic structures, a TCO layer is formed on each side. Subsequently, a patterned mask can be formed on each of the TCO layers (operation 1006). As discussed previously, the patterned mask can define a grid having multiple sub-grids, with a busbar that includes one or more thermal-stress-release structures located at the edge of each sub-grid. In some embodiments, the thermal-stress-release structures can include gaps separating segments of a busbar. In some embodiments, the thermal-stress-release structures can include a continuous metallic strip having a varying width, the width being periodically modulated. Alternatively, the thermal-stress-release structures can include a zigzagged busbar, with sections of the busbar zigzagged along the edge of a sub-grid.

Subsequently, metallic grids can be formed using the patterned masks, completing the fabrication of the photovoltaic structure (operation 1008). Forming a metallic grid can involve depositing, using a PVD technique, a metallic seed layer (e.g., a Cu seed layer) on the TCO layer, and depositing, using a plating technique, a metallic bulk layer (e.g., an electroplated Cu layer) on the seed layer. In some embodiments, the metallic grid can also include a cap layer (e.g., a Sn layer), formed using a plating technique, on top of the metallic bulk layer. A thermal annealing process can also be performed to anneal the TCO layers and the metallic seed layers. In further embodiments, forming the metallic grids can also involve applying an organic solderability preservative (OSP) coating over the metallic grids to preventing oxidation and corrosion of the grids.

The fabricated photovoltaic structure can then be sent to an automated tool for panel fabrication, where conductive paste can be applied onto the busbars (operation 1010), and the photovoltaic structures can be divided into smaller strips (operation 1012). In alternative embodiments, the photovoltaic structures may first be divided into smaller strips before the conductive paste is applied onto the busbars. Special care is needed when applying the conductive paste to ensure that the paste is aligned to busbar segments or the paste is applied as separated droplets.

The strips can then be cascaded into strings (operation 1014). More specifically, within a string, adjacent solar strips can be arranged in a way that their edge busbars overlap with conductive paste sandwiched in between. Heat and pressure can be applied to the string to cure the conductive paste. Multiple strings can be laid out and interconnected, either in series or in parallel, to obtain a module (operation 1016).

In general, embodiments of the present invention provide a photovoltaic structure with specially designed edge busbars. By forming busbars having stress-release structures, the problem of bond failure for a cascaded

The foregoing descriptions of various embodiments have been presented only for purposes of illustration and description. They are not intended to be exhaustive or to limit the invention to the forms disclosed. Accordingly, many modifications and variations will be apparent to practitioners skilled in the art. Additionally, the above disclosure is not intended to limit the invention.

What is claimed is:

1. An electrode grid of a photovoltaic structure, comprising:
a plurality of finger lines;
a busbar coupled to the plurality of finger lines, wherein the busbar includes one or more stress-release structures, thereby reducing stress caused by thermal expansion mismatch between the busbar and underlying layers of the photovoltaic structure.

2. The electrode grid of claim 1, wherein the busbar includes segments of a metallic strip, and wherein a respective stress-release structure includes a gap positioned between two adjacent segments of the metallic strip.

3. The electrode grid of claim 2, wherein the two adjacent segments are electrically coupled to each other by a metallic line having a width smaller than a width of the metallic strip.

4. The electrode grid of claim 1, wherein the busbar includes a continuous metallic strip having a varying width.

5. The electrode grid of claim 4, wherein the width of the continuous metallic strip is periodically modulated.

6. The electrode grid of claim 1, wherein the busbar includes a continuous zigzag-shaped metallic strip along a length of the photovoltaic structure.

7. The electrode grid of claim 1, wherein the finger lines and busbar include an electroplated Cu layer.

8. A solar cell, comprising:
a multilayer photovoltaic structure;
a first metallic grid positioned on a first surface of the photovoltaic structure, wherein the first metallic grid includes a first busbar; and
a second metallic grid positioned on a second surface of the photovoltaic structure, wherein the second metallic grid includes a second busbar;
wherein the first and second busbars each include one or more stress-release structures, thereby reducing stress caused by thermal expansion mismatch between the busbars and the multilayer photovoltaic structure.

9. The solar cell of claim 8, wherein the first and second busbars each include segments of a metallic strip, and wherein a respective stress-release structure includes a gap positioned between two adjacent segments of the metallic strip.

10. The solar cell of claim 9, wherein the two adjacent segments are electrically coupled to each other by a metallic line having a width smaller than a width of the metallic strip.

11. The solar cell of claim 8, wherein the first and second busbars each include a continuous metallic strip having a varying width, and wherein the width of the continuous metallic strip is periodically modulated.

12. The solar cell of claim 8, wherein the first and second busbars each include a continuous zigzag-shaped metallic strip along a length of the photovoltaic structure.

13. The solar cell of claim 8, wherein the multilayer photovoltaic structure comprises:
a base layer;
a first quantum tunneling barrier layer positioned on a first surface of the base layer;
a second quantum tunneling barrier layer positioned on a second surface of the base layer;
an emitter layer positioned on the first quantum tunneling barrier layer;
a surface field layer positioned on the second quantum tunneling barrier layer;
a first transparent conductive oxide layer positioned on the emitter layer; and
a second transparent conductive oxide layer positioned on surface field layer.

14. A photovoltaic module, comprising:
a plurality of photovoltaic structures, wherein a respective photovoltaic structure comprises:
a multilayer structure;
a first metallic grid comprising a first edge busbar positioned on a first surface of the multilayer structure;
a second metallic grid comprising a second edge busbar positioned on a second surface of the multilayer structure, wherein the first and second edge busbars are positioned on opposite edges and opposite sides of the photovoltaic structure;
wherein the photovoltaic structures are arranged in such a way that the first edge busbar of a first photovoltaic structure overlaps with the second edge busbar of an adjacent photovoltaic structure, with conductive paste positioned between the first and second edge busbars; and
wherein the first and second edge busbars each include one or more stress-release structures, thereby reducing stress caused by thermal expansion mismatch between the busbars and the conductive paste.

15. The photovoltaic module of claim 14, wherein the first and second edge busbars each include segments of a metallic strip, and wherein a respective stress-release structure includes a gap positioned between two adjacent segments of the metallic strip.

16. The photovoltaic module of claim 15, wherein the two adjacent segments are electrically coupled to each other by a metallic line having a width smaller than a width of the metallic strip.

17. The photovoltaic module of claim 14, wherein the first and second edge busbars each include a continuous metallic strip having a varying width, and wherein the width of the continuous metallic strip is periodically modulated.

18. The photovoltaic module of claim 14, wherein the first and second edge busbars each include a continuous zigzag-shaped metallic strip along an edge of the photovoltaic structure.

19. The photovoltaic module of claim 14, wherein the multilayer structure comprises:
a base layer;
a first quantum tunneling barrier layer positioned on a first surface of the base layer;
a second quantum tunneling barrier layer positioned on a second surface of the base layer;
an emitter layer positioned on the first quantum tunneling barrier layer;
a surface field layer positioned on the second quantum tunneling barrier layer;
a first transparent conductive oxide layer positioned on the emitter layer; and
a second transparent conductive oxide layer positioned on surface field layer.

20. The photovoltaic module of claim 14, wherein the first and second metallic grids each include an electroplated Cu layer, and wherein the conductive paste includes a plurality of Cu particles suspended in resin.
